(19) United States
(12) Patent Application Publication
(10) Pub. No.: US 2019/0211444 A1
(43) Pub. Date: Jul. 11, 2019

(54) SEMICONDUCTOR PROCESS KIT WITH 3D PROFILING

(71) Applicant: NOVENA TEC INC., MARKHAM (CA)

(72) Inventors: ROMMEL MONTES, CALGARY (CA); EDMER GADO, SANTA ROSA (PH); CHAMIL BANDARANAYAKE, KALAGEDIHENA (LK)

(21) Appl. No.: 15/866,019

(22) Filed: Jan. 9, 2018

(51) Int. Cl. C23C 16/44; C23C 14/34; C23C 14/56

(52) U.S. Cl. CPC C23C 16/4404; C23C 14/564; C23C 14/3457

(57) ABSTRACT

A process kit for use in a deposition chamber comprises a parent part and a disposable insert. The parent part receives the disposable insert to form a complete process kit. The disposable insert prevents the contact of any surface of the parent part to a deposited thin film A portion of an inner surface of the disposable insert comprises a plurality of recesses where the density of the plurality of recesses is proportional to the amount of the deposited thin film that accumulates on the portion of an inner surface when in use.

### BACKGROUND OF THE INVENTION

### Field of the Invention

The present invention relates to semiconductor process kits and more particularly to process kits used for CVD and PVD processes.

### Description of Related Art

Semiconductor processes involve the deposition and removal of multiple thin layers. Deposition can be done in various ways including chemical vapor deposition (CVD) and physical vapor deposition (PVD). Depositions is commonly done in a process chamber. A wafer being processed is placed in the chamber and a sputtering gas containing the material to be deposited is introduced into the chamber where it condenses on the surface of the wafer. The process kit controls particles and sputtering gas during particle deposition on the substrate.

Process kits control the particle deposition on the wafer that also serves as a deposition surface for excess particles to avoid defects on the wafer during deposition. These process kits can only hold a certain amount of deposit particles after which the defect rate of wafers starts to increase. Based on schedules, used process kits are removed from use and refurbished by chemical cleaning to remove the deposited particles. Having to take a process chamber off-line for maintenance and cleaning is disruptive and expensive, since no deposition can be performed until the process kit is returned. This leads to underutilized equipment and reduced overall yield.

Each time a process kit is cleaned, the surface of the process kit is degraded until it can no longer be cleaned and reaches the end of its lifespan. At the end of their lifespan, process kits must be disposed of and be replaced by a new process kit. Process kits are a significant expense and the length of time a process kit can be used before being discarded has a real impact on the operating cost of the process chamber.

There exists a need for an improved process kit with reduced cost, longer life, and that can be cleaned and maintained while minimizing or reducing down time. At the same time, it would be beneficial to reduce the defect rate of wafers processed with the process kit.

Other aspects and features of the present invention will become apparent to those ordinarily skilled in the art upon review of the following description of specific embodiments of the invention in conjunction with the accompanying figures.

### BRIEF SUMMARY OF THE INVENTION

It is an object of the present invention to provide a process kit for use in a deposition chamber. The process kit comprises a parent part, and a disposable insert. The parent part receives the disposable insert to form a complete process kit. The disposable insert prevents the contact of any surface of the parent part to a deposited thin film

In some embodiments, a portion of an inner surface of the disposable insert comprises a plurality of recesses. The density of the plurality of recesses is proportional to the amount of the deposited thin film that accumulates on the portion of an inner surface when in use. In some embodiments, the plurality of recesses are half spherical in shape. In some embodiments, the plurality of recesses are formed using a mechanical drilling process. In other embodiments, the plurality of recesses are formed using a laser removal process.

In some embodiments, the parent part comprises a first alignment mechanism and the disposable insert comprises a second alignment mechanism, the first alignment mechanism receiving the second alignment mechanism when the disposable insert is inserted into the parent part.

Other aspects and features of the present invention will become apparent to those ordinarily skilled in the art upon review of the following description of specific embodiments of the invention in conjunction with the accompanying figures.

### BRIEF DESCRIPTION OF THE SEVERAL VIEWS OF THE DRAWING(S)

Embodiments of the present invention will now be described, by way of example only, with reference to the attached Figures, wherein:

FIG. 1 illustrates a process kit as used in a semiconductor manufacturing process;

FIG. 2 illustrates a process kit as used in a semiconductor manufacturing process where flaking of deposited material occurs;

FIG. 3 illustrates a parent part and inner insert according to embodiments of the invention.

FIG. 4 illustrates a pattern of nano-structures in planar view according to embodiments of the invention.

FIGS. 5A and 5B depict a pattern of nano-structures in a profile view with and without adhered deposited particles.

FIG. 6 depicts various shapes of nano-structures in a profile view.

FIG. 7 depicts a pattern of nano-structures in a perspective view.

FIG. 8 depicts a top view of a pattern of nano-structures arranged in rows and columns.

FIG. 9 depicts a top view of a pattern of nano-structures arranged in offset rows and columns.

FIG. 10 depicts a top view of a pattern of nano-structures arranged in offset rows and columns with a relaxed spacing.

FIG. 11 depicts a top view of a pattern of nano-structures arranged in offset rows and columns with key detentions between the nano-structures illustrated.

FIG. 12 depicts a tab and slot arrangement used to align the parent part with the inner insert.

FIG. 13 depicts a floating screw mechanism to secure the inner insert in the parent part.

### DETAILED DESCRIPTION OF THE INVENTION

The present invention is direct to semiconductor process kits and more particularly to a two-part process kit comprising a semi-permanent parent part and a replaceable insert including a novel nano-structure surface on process kit components where PVD or CVD particles accumulate.

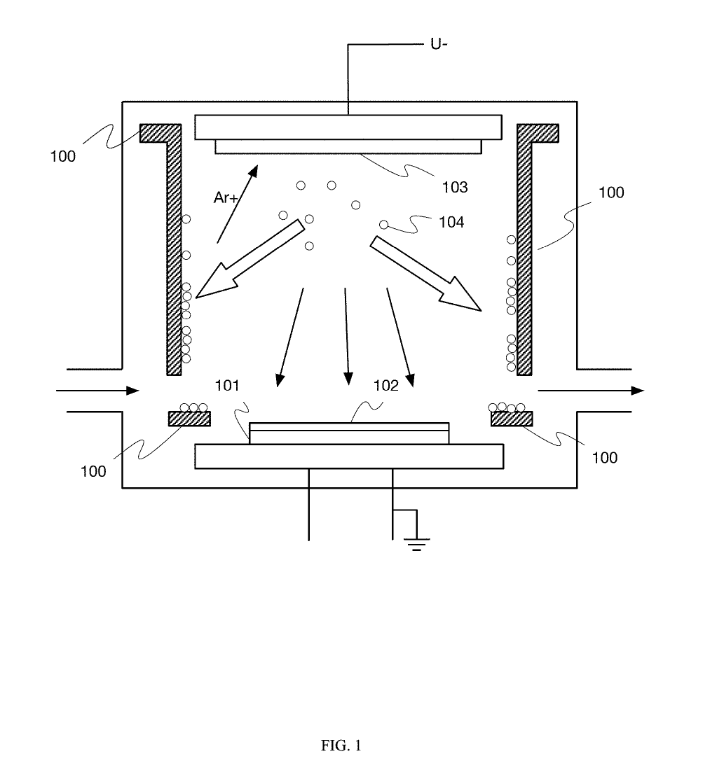

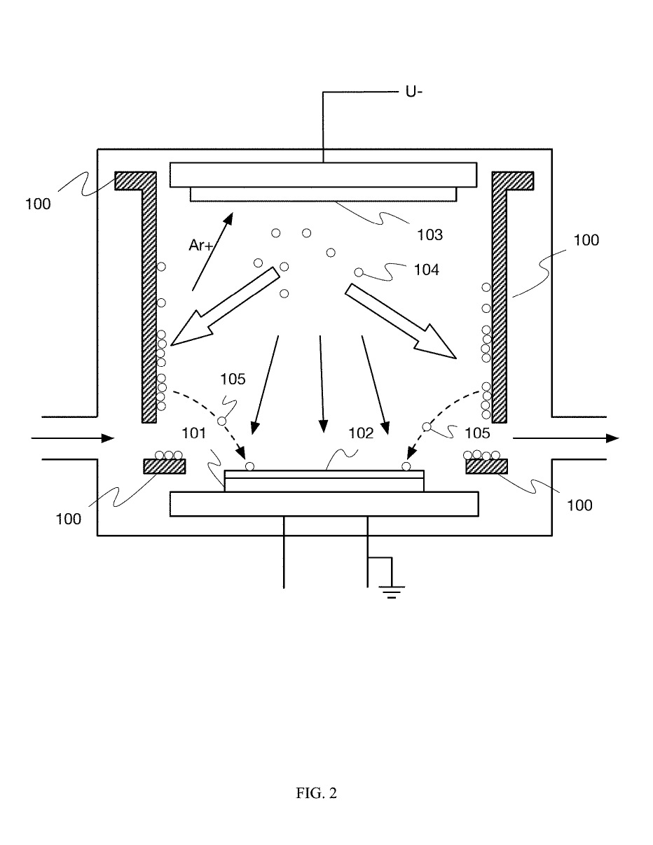

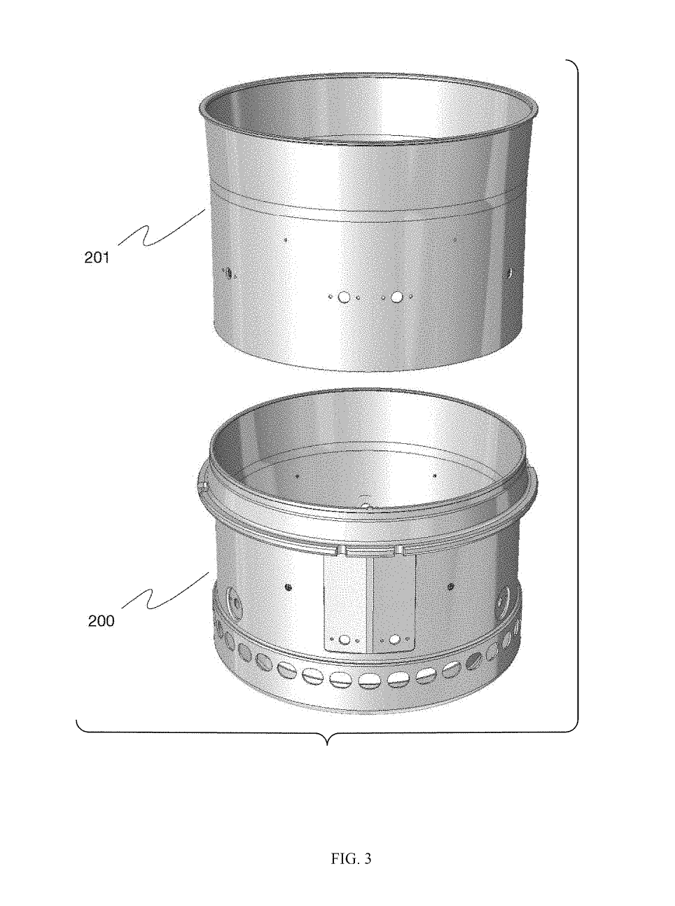

As shown in FIG. 3, embodiments of the invention comprise a non-consumable parent part 200 that receives a replaceable insert 201 with nano-structures 106 on portions of its interior surface. The combination of the parent part 200 and the insert 201, when combined, have a compatible profile and size and may be used in place of a prior art single part process kit 100 as illustrated in FIG. 1 and FIG. 2.

The parent part 200 is manufactured using aluminum, stainless steel, or other suitable material. It may be manufactured using conventional subtractive or additive processes as required by the process kit design requirements. Subtractive processes include milling, lathe work, metal spinning processes, and welding process. Additive processes include 3D printing and similar processes.

Embodiments of the invention may be used as original equipment (OEM) or may be used as substitute parts for traditional, single part process kit parts. When used as substitute parts, the parent part 200 will have an outer surface and shape to be compatible with the process kit parts it is replacing.

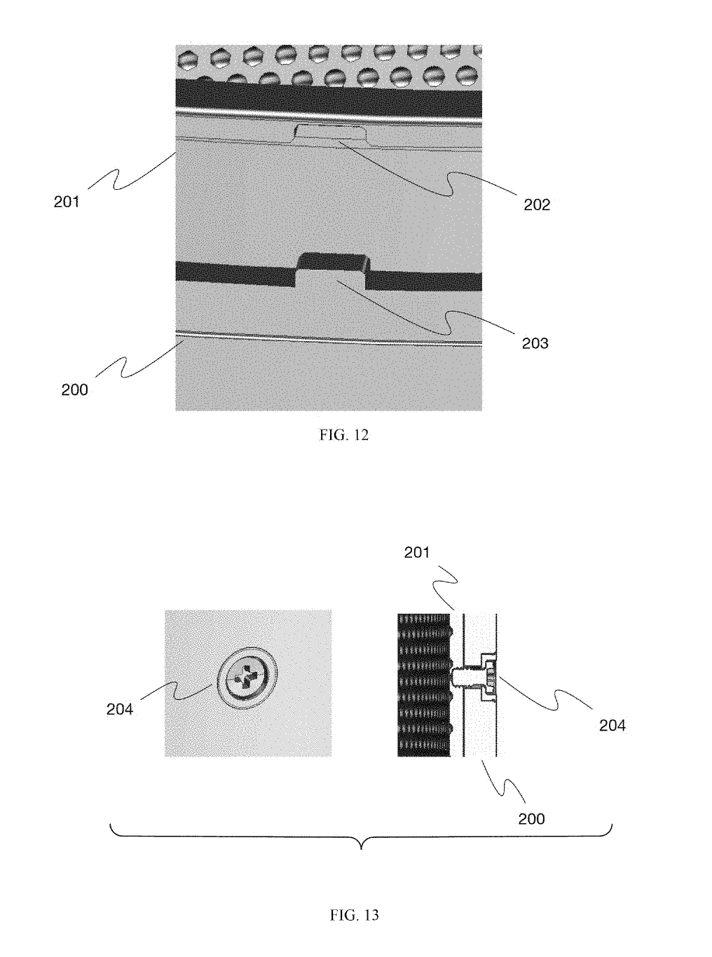

As shown in FIG. 12, the parent part comprises alignment and retaining mechanisms to allow the parent part 200 to receive the insert 201 correctly and to securely retain it in place. Examples of alignment mechanisms include tabs 203, slots 202, or holds that will receive similar features incorporated in the insert 201. Examples of retaining mechanisms include fasteners such as captive screws 204, as shown in FIG. 13.

When in use, the parent part 200 surfaces that may make contact with PVD or CVD gases and particles are shielded by the insert 201 and are only minimally exposed to or not exposed to deposited particles 104. As a result of this, the parent part receives only minimal or no deposition and requires no cleaning or only minimal cleaning. In some applications, the parent part may be permanently attached to the deposition chamber or designed as a part of the chamber.

The parent part is not exposed to material deposit and can be used for a much longer time before being replaced. This makes it economical to integrate further features into the process kit such as integrating a water cooler into the parent part.

Embodiments of the invention comprise a replaceable insert 201 that fits inside the patent part 200 to form a process kit 100. The insert 201 is manufactured using aluminum, stainless steel, or other suitable material. It may be manufactured using conventional subtractive or additive processes as required by the process kit design requirements. Subtractive processes include milling, lathe work, metal spinning processes, and welding process. Additive processes include 3D printing and similar processes.

Embodiments of the invention may be used as original equipment (OEM) or may be used as substitute parts for traditional, single part process kit parts. When used as substitute parts, the insert 201 will have an inner surface and shape to be compatible with the process kit parts it is replacing. By making the inner surface of the insert 201 as close as possible to the OEM part, embodiments of the invention may be used as replacements for the OEM part without affecting the manufacturing process.

The insert 201 comprises alignment and retaining mechanisms to allow the insert to be correctly received by the parent part and to securely retain it in place. Examples of alignment mechanisms include tabs 203, slots 202, or holds that will receive similar features incorporated in the insert. Examples of retaining mechanisms include fasteners such as captive screws 204, as shown in FIG. 13.

Referring to FIG. 2, the insert is designed so that when the parent part 200 and insert 201 are combined and secured to form a process kit 100, only the surfaces of the insert make contact with PVD or CVD gases and particles 104. As a result of this the insert 201 receives the majority of the deposited particles 104. An insert 201 can only receive a maximum amount of particles before flakes 105 of deposited material form. These flakes 105 can break loose and cause defects in the wafers 102 being manufactured. Before this can happen the insert 201 may be replaced with a new or refurbished insert, minimizing the time that the process chamber is offline. The removed insert may be refurbished by removing the deposit through chemical means or discarded.

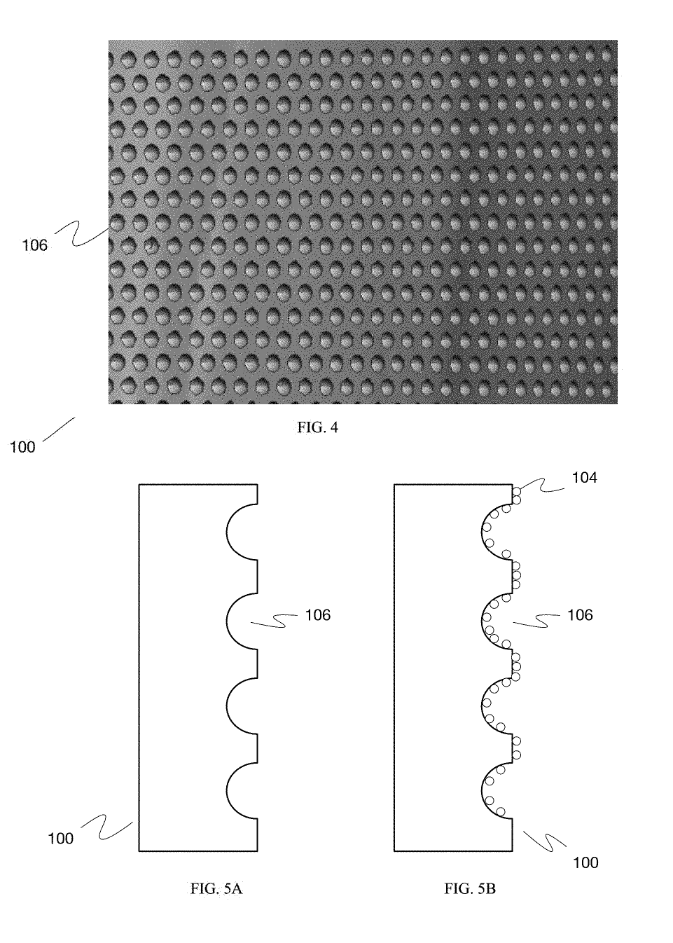

In order to extend the performance of the insert 201, surfaces of the insert that are exposed to PVD or CVD gases and particles 104 may have a pattern of nano-structures 106 formed in them as illustrated in FIG. 4. As shown in FIG. 5, the nano-structures are formed within the insert surface (FIG. 5A) and provide additional surface area for deposition particles to adhere to (FIG. 5B). In some embodiments, the nano-structures provide an approximately 30% increase in deposition area. The increased surface area and texture of the nano-structures increases the use time before flaking may occur extending the time an insert may be used before being cleaned or refurbished. The nano-structures provide the benefit of reducing the number of both large and small flakes 105.

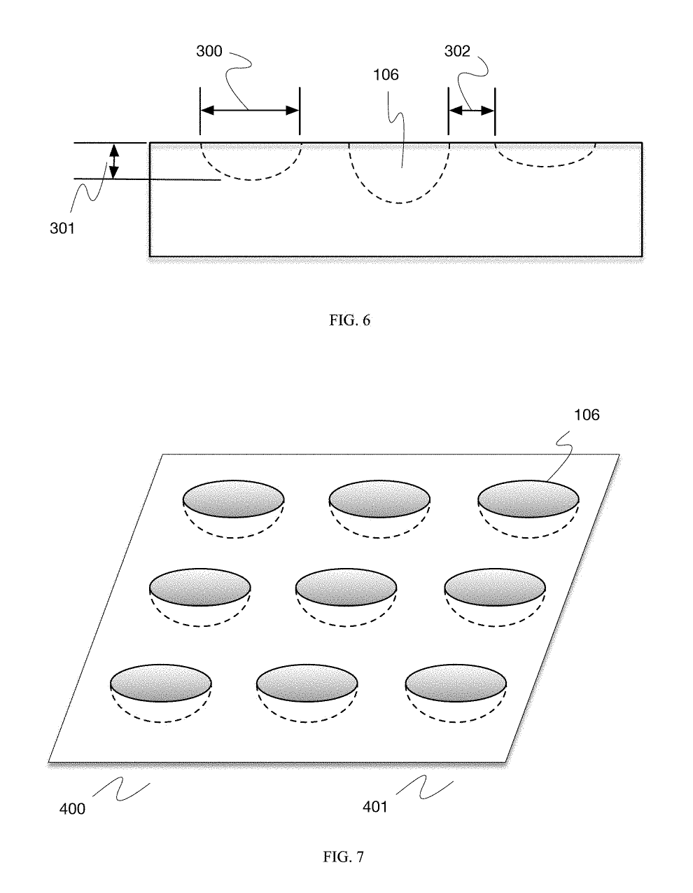

Nano-structure geometries are shown in FIG. 6 and may vary based on the process requirement or customer preference. The nano-structures are permanently applied in the insert's identified surface. The pattern and density of the nano-structures may be uniform over a small area but are often non-uniform over the entire surface of the insert. The distribution of the nano-structure may vary over the surface area of the insert and some surfaces may have no nano-structures at all. The placement and pattern of the nano-structures help to counter balance and distribute the deposited film stress that occurs during their use in PVD and CVD processes. The density, pattern, shape, and dimensions of the nano-structures may vary over the surfaces of insert, having a higher or lower density of nano-structures depending on the amount of stress experienced by thin film depositions when in use. In general, the higher the amount of stress, the more nano-structures should be used. By varying the amount and density of nano-structures the stress may be uniformly distributed over the insert.

The quantity of the nano-structure may vary depending on the size of the insert as for a larger insert there is more area to fit nano-structures in. By calculating the relevant surface area and setting the design distances it is possible to calculate the number of nano-structure that may be placed. In preferred embodiments, the minimum distance between nano-structures is determined by manufacturing tolerances and techniques. In preferred embodiments, each nano-structure has an approximately half-spherical or semi-spherical shape and is formed into the surface of the kit part. In cases where the depth 301 of the nano-structure is less than half the diameter 300, the shape will be semi-spherical. In cases where the depth 301 of the nano-structure is approximately the same as the radius of the structure the shape will be half-spherical. In most embodiments, the bottom of the nano-structure will have a round shape in order to maximize the surface area. Referring to FIG. 6, in an exemplary embodiment, each nano-structure is 2 mm in diameter 300 in the horizontal plane, 1 mm in depth 301, with 1 mm between 302 adjacent nano-structures. In another exemplary embodiment, each nano-structure is 3 mm in diameter 300 in the horizontal plane, 0.7 mm in depth 301. Nano-structures of different diameters, depth, and spacing may also be combined in the same insert. Other sizes and shapes may be determined experimentally for different applications.

The nano-structures themselves may be formed in a number of ways including mechanical drilling, or laser removal of material. In general, the more nano-structures the better with the number of nano-structures and their density determined by the manufacturing process used and their tolerances. In other embodiments, the insert with nano-structures may be further processed with sand blasting or by the application of an aluminum coating to further increase the surface roughness.

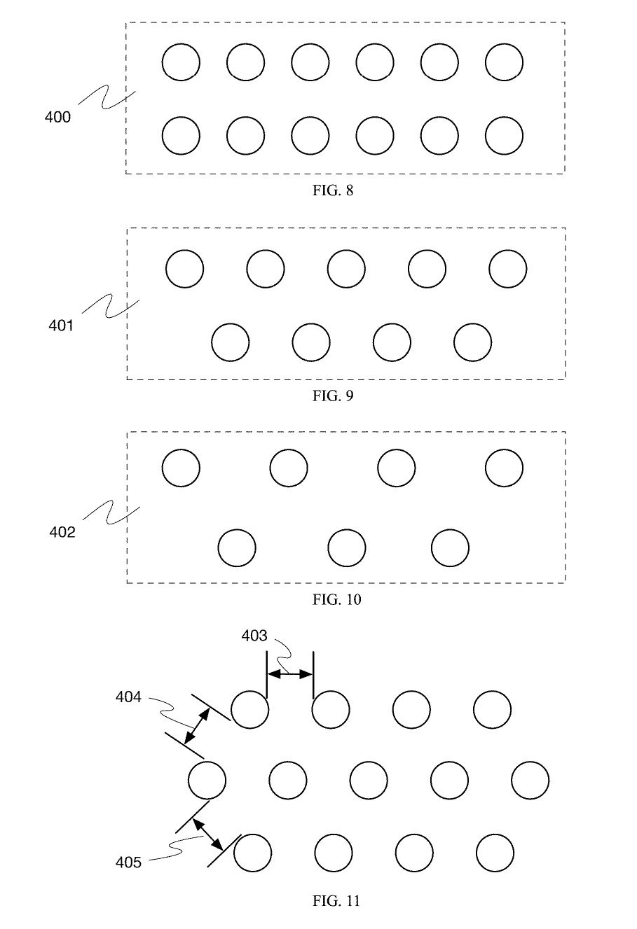

FIG. 8, FIG. 9, and FIG. 10 illustrated different layouts and spacing that may be used in embodiments of the invention. In general, where particle deposition is high, more nano-structures should be added leading to a higher density of nano-structures. Optimal placements, patterns, and density of the nano-structures can be determined experimentally by examining where the flaking of deposited film starts, where arcing occurs, where plasma leaks, where heat distribution is uneven, and other manufacturing issues manifest themselves. Nano-structures should be placed where manufacturing issues are most likely to happen and where experimentation has shown them to improve the process.

FIG. 8 illustrates a nano-structure layout where the nano-structures in adjacent rows are aligned in both the x and y direction.

FIG. 9 illustrates a nano-structure layout where the nano-structures in adjacent rows may be offset from each other in either the x or y direction.

FIG. 10 illustrates a less dense nano-structure layout where the nano-structures in adjacent rows may be offset from each other in either the x or y direction.

FIG. 11 illustrates a nano-structure layout where the nano-structures in adjacent rows may be offset from each other in either the x or y direction. The distances 403, 404, and 405 between nano-structures are determined experimentally within the limits of manufacturing technology.

In some embodiments, the insert may have nano-structures placed for an optimized profile to minimize or eliminate “target” level arcing and to minimize or eliminate plasma leak issues. The nano-structures may also be placed to minimize or eliminate stress build up during annealing processes.

Pasting is a cleaning recipe that is run inside the process chamber using a Shutter Disk. The purpose is to “paste” a new layer of material on the process kit's internal surfaces to cover any existing loose material and prevent it from flaking off or dropping to the wafer surface during production wafer processing. Using embodiments of the invention with nano-structures an increased number of wafers may be processed before running the pasting recipe when compared to process kits that do not use nano-structures.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

What is claimed is:

1. A process kit for use in a deposition chamber, the process kit comprising:
a parent part, and
a disposable insert, the parent part receiving the disposable insert to form a complete process kit, the disposable insert preventing the contact of any surface of the parent part to a deposited thin film

2. The process kit of claim 1 wherein a portion of an inner surface of the disposable insert comprises a plurality of recesses.

3. The process kit of claim 2 wherein the density of the plurality of recesses is proportional to the amount of the deposited thin film that accumulates on the portion of an inner surface when in use.

4. The process kit of claim 2 wherein the plurality of recesses are half spherical in shape.

5. The process kit of claim 2 wherein the plurality of recesses are formed using a mechanical drilling process.

6. The process kit of claim 2 wherein the plurality of recesses are formed using a laser removal process.

7. The process kit of claim 2 wherein parent part comprises a first alignment mechanism and the disposable insert comprises a second alignment mechanism, the first alignment mechanism receiving the second alignment mechanism when the disposable insert is inserted into the parent part.

8. The process kit of claim 2 wherein the plurality of recesses are formed using a laser removal process.
